(19) United States
(12) Patent Application Publication
(10) Pub. No.: US 2024/0075552 A1
(43) Pub. Date: Mar. 7, 2024

(54) LASER BEAM IRRADIATION DEVICE FOR FULL CUTTING OF SEMICONDUCTOR AND OPERATION METHOD THEREOF

(71) Applicant: XELINCOMPANY Co. Ltd., Seoul (KR)

(72) Inventor: Jang Su JUN, Incheon (KR)

(73) Assignee: XELINCOMPANY Co. Ltd., Seoul (KR)

(21) Appl. No.: 17/929,961

(22) Filed: Sep. 6, 2022

(51) Int. Cl. B23K 26/08; B23K 26/06; B23K 26/38; H01L 21/67

(52) U.S. Cl. CPC B23K 26/08; B23K 26/0604; B23K 26/0648; B23K 26/38; H01L 21/67092; B23K 2101/40

(57) ABSTRACT

A laser beam irradiation device for processing a semiconductor includes a laser beam outputter configured to cause a laser beam to travel in a direction of processing to process a semiconductor, and to vibrate the laser beam at a constant amplitude in a direction of vibration different from the direction of processing; and a condenser lens configured to form a laser spot on the semiconductor, the laser spot traveling in the direction of processing and vibrating in the direction of vibration.

### BACKGROUND

### 1. Field of the Invention

The technical idea of the present disclosure relates to a laser beam radiation device for fully cutting a semiconductor and an operation method thereof, and more particularly, to a laser beam irradiation device for preventing optical damage to a semiconductor device and an operation method thereof.

### 2. Discussion of Related Art

In accordance with the rapid development of the electronic industry and user demand, electronic devices are being developed to be more compact, more highly integrated, and larger. Accordingly, sizes of semiconductor devices included in electronic devices are becoming micro-areas of nanometers.

Examples of a semiconductor processing method related to the present disclosure include dicing that is a type of a cutting process of cutting and dividing a large-scale wafer into a plurality of chips, a grinding process of making a wafer thinner, and a grooving process of forming a groove to form a conductive interconnection.

In relation to dicing, blade dicing that is a method of cutting a substrate with a thin cutting blade formed of micro-diamond is used. However, in a process of cutting a substrate with a cutting blade, chipping may occur in a surface or back of the substrate and the performance of chips divided from the substrate may be degraded due to the chipping.

As another type of dicing, stealth dicing is used to concentrate a laser beam on a local area to form internal cracks for cutting. However, a laser beam used for stealth dicing has extremely high peak power and thus may cause cracks in a surface of a semiconductor during the formation of the internal cracks, resulting in degradation of the performance of chips.

### SUMMARY OF THE INVENTION

The present disclosure is directed to providing a laser beam irradiation device for semiconductor processing, which is capable of vibrating a laser beam to reduce the accumulation of heat energy due to the concentration of a laser, thereby improving the performance of chips, and an operation method thereof.

According to an aspect of the present disclosure, a laser beam irradiation device for processing a semiconductor includes a laser beam outputter configured to cause a laser beam to travel in a direction of processing to process a semiconductor, and to vibrate the laser beam at a constant amplitude in a direction of vibration different from the direction of processing, and a condenser lens configured to form a laser spot on the semiconductor, the laser spot traveling in the direction of processing and vibrating in the direction of vibration.

The laser beam outputter may output a first laser to the semiconductor in the direction of processing for first-time processing and output a second laser at an incidence angle different from an incidence angle of the first laser in the direction of processing.

The laser beam outputter may include a first laser beam outputter configured to output the first laser to perform pre-processing for cutting the semiconductor while securing high processing quality, and a second laser beam outputter configured to output the second laser for forming a cut surface on the semiconductor.

The laser beam outputter may further include a laser oscillator configured to oscillate and output the laser beam, and a vibrator configured to physically vibrate an optical element to vibrate the laser beam, which is incident from the laser oscillator, in the direction of vibration.

The laser oscillator and the condenser lens may be fixed not to vibrate, and the optical element may make a simple harmonic motion due to a driving force of a motor of the vibrator.

The optical element may include a horizontal mirror, and the motor may include at least one of an ultrasound motor and a resonance motor.

The laser beam irradiation device may further include an inputter configured to receive a manipulation command for processing the semiconductor, and a controller configured to control the vibrator to apply an input of a sine wave to the motor in a first mode and apply a triangular or square wave to the motor in a second mode, based on the manipulation command.

The first mode may be a user mode selected by a user who assigns priority to a vibration speed of the laser beam, and the second mode may be a user mode selected by a user who assigns priority to a vibration amplitude of the laser beam.

The optical element may include a pair of polygonal mirrors each having a plurality of reflective surfaces, and the pair of polygonal mirrors may rotate in different directions.

The semiconductor may include a semiconductor substrate, and the condenser lens may output the laser beam at an angle of incidence in a direction perpendicular to a plane of the semiconductor.

The angle of incidence may substantially coincide with a right angle, and the laser beam outputter may vibrate the laser beam at a vibration amplitude in the direction of vibration to correspond to a distance determined by a line width of the semiconductor substrate.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a conceptual diagram for describing a laser beam irradiation device according to an embodiment of the present disclosure;

FIGS. 2A and 2B are diagrams for describing a processing method of a laser beam irradiation device according to an embodiment of the present disclosure;

FIGS. 3A and 3B are diagrams for describing blade dicing and stealth dicing of the related art;

FIGS. 4A to 4C are diagrams for describing a method of vibrating a laser beam according to an embodiment of the present disclosure;

FIG. 5 is a diagram for describing a vibration method, a condenser lens, and a processing method of a laser beam irradiation device according to an embodiment of the present disclosure;

FIGS. 6A and 6B are diagrams for describing mirror vibration among vibration methods according to an embodiment of the present disclosure;

FIGS. 7A and 7B are diagrams for describing polygon vibration among vibration methods according to an embodiment of the present disclosure;

FIGS. 8A and 8B are diagrams for describing light-source vibration among vibration methods according to an embodiment of the present disclosure;

FIGS. 9A and 9B are diagrams for describing a condenser lens according to an embodiment of the present disclosure;

FIGS. 10A and 10B are diagrams for describing a direction of vibration and a direction of processing determined by a processing method according to an embodiment of the present disclosure;

FIGS. 11A to 11C are diagrams for describing a direction of processing and an angle of incidence according to an embodiment of the present disclosure; and

FIGS. 12A to 13B are images taken by an electron microscope for describing the quality of a semiconductor processing result according to an embodiment of the present disclosure, together with a comparative example.

### DETAILED DESCRIPTION OF EXEMPLARY EMBODIMENTS

Hereinafter, embodiments of the inventive concept will be described in detail with reference to the accompanying drawings.

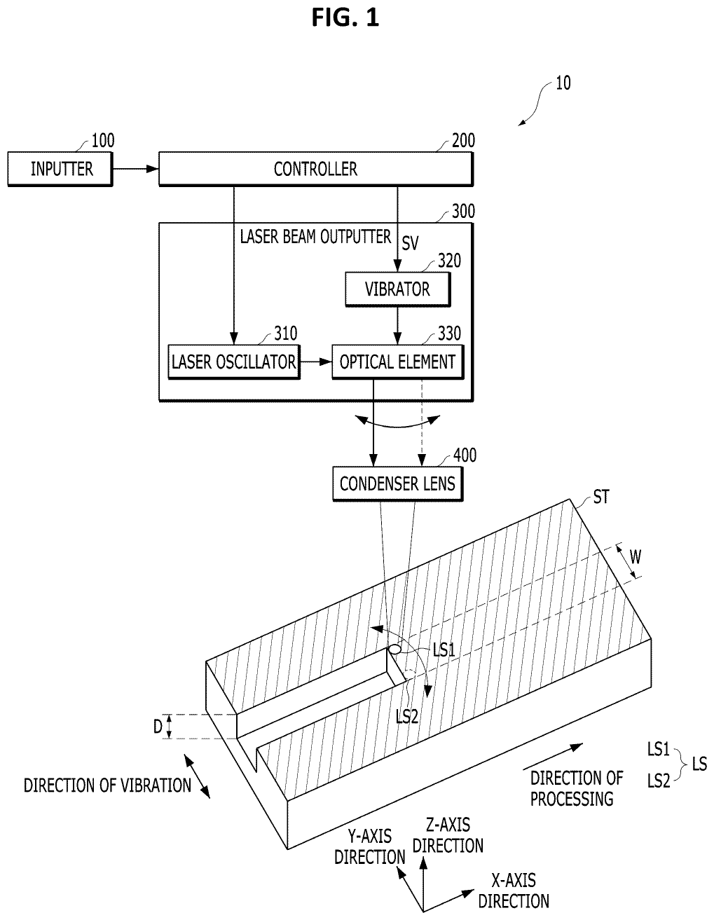

FIG. 1 is a conceptual diagram for describing a laser beam irradiation device according to an embodiment of the present disclosure.

Referring to FIG. 1, the laser beam irradiation device 10 may include an inputter 100, a controller 200, a laser beam outputter 300, and a condenser lens 400. The laser beam outputter 300 may include a laser oscillator 310, a vibrator 320, and an optical element 330.

The laser beam irradiation device 10 may output a laser beam to form a laser spot LS on an object ST to be irradiated.

Examples of the object ST may include a semiconductor substrate and a wafer. For convenience of description, the object ST may be described as a semiconductor, a semiconductor substrate or a semiconductor wafer. In this case, a substrate may be processed by various methods using thermal energy of a laser beam, and the various methods may include dicing for cutting and dividing a large-scale wafer into a plurality of chips, grinding for making a wafer thinner, and grooving for forming a groove to form a conductive interconnection.

Examples of the object ST may include a semiconductor film (e.g., an oxide film). For example, a semiconductor film may be annealed by the laser beam irradiation device 10.

Hereinafter, “processing” may be understood to mean a process of the laser beam irradiation device 10 causing physical deformation of the object ST with a laser beam, and technical ideas of the present disclosure are not limited by the examples described above.

According to an embodiment of the present disclosure, the laser beam irradiation device 10 may vibrate a laser beam to reduce the accumulation of heat energy concentrated according to the laser spot LS.

Specifically, the laser beam irradiation device 10 may cause a laser beam to travel in a direction of processing to process the object ST. In addition, the laser beam irradiation device 10 may vibrate the laser beam at a constant amplitude (processing amplitude) in a direction of vibration that is different from the direction of processing. Therefore, a defect rate of the object ST may be reduced by vibrating the laser beam on a second laser spot LS2 before deformation of the object ST due to excessive accumulation of heat energy on a first laser spot LS1.

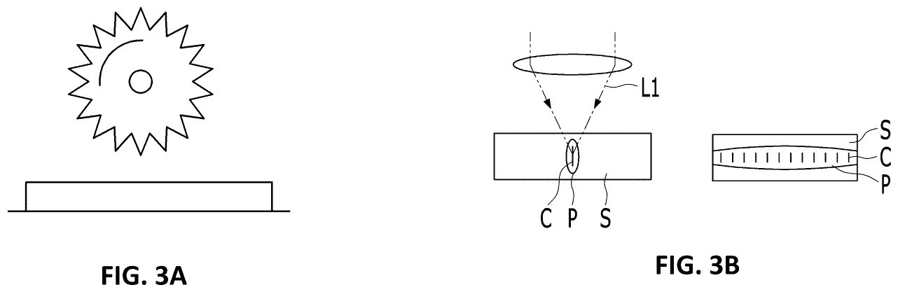

As will be described with reference to FIGS. 3A and 3B below, the laser beam irradiation device 10 may vibrate the laser beam at a constant amplitude in a direction of vibration that is the same as the direction of processing. By using a laser beam vibrating in the same direction as the direction of processing, the laser beam irradiation device 10 may discharge emissions (e.g., dust, particles or debris), which are generated during processing of the object ST, out of a processing area or remove the emissions on the basis of the vibrating laser beam. Accordingly, a reduction of the yield due to the emissions may be prevented.

The inputter 100 may receive a manipulation command from a user. For example, the manipulation command may include a command for instructing a user to determine a width of a line to be engraved in the object ST, and as another example, the manipulation command may include a command for controlling a processing rate of the object ST.

The inputter 100 may receive information about a first mode or a second mode selected by a user. The first mode may be a user mode in which priority is assigned to a vibration speed of a laser beam, and the second mode may be a user mode in which priority is assigned to a vibration amplitude of a laser beam. Processing methods in the first and second modes will be described together with the controller 200 below.

The inputter 100 may be embodied as a device (e.g., a keyboard) or software (an input user interface) for receiving a manipulation command from a user and transmitting the manipulation command to the controller 200. Alternatively, the inputter 100 may be an input interface of an operating system (O/S). The present disclosure is not limited thereto, and the inputter 100 may include various types of hardware, software, or firmware input means.

The controller 200 may output an oscillation signal SO to control the laser oscillator 310.

The laser oscillator 310 may include various types of oscillators for processing the object ST such as a semiconductor device, a semiconductor component, or an element included in the semiconductor device. For example, the laser oscillator 310 may include a laser of several hundreds of watts to a laser of several hundreds of kilowatts. The oscillation signal SO may control overall operations of the laser oscillator 310.

The controller 200 may output a vibration signal SV to control the vibrator 320. The vibration signal SV may include information about a vibration amplitude, a vibration speed and an input waveform. For example, the vibrator 320 may include a resonance motor. Hereinafter, the resonance motor may be understood to be a driving device that vibrates as a vibrator resonates and may have a frequency higher than that of a galvo motor.

The controller 200 may apply different input waveforms to the vibrator 320 on the basis of a plurality of user modes, including the first and second modes. Here, the input waveforms may include a waveform of an electrical signal supplied to drive the motor.

The controller 200 may output the vibration signal SV to apply an input of a sine wave to the motor of the vibrator 320 in the first mode, based on the manipulation command. The motor to which the input of the sine wave is applied may maximize a vibration speed of a laser beam. That is, the accuracy of a vibration amplitude may be lower than in the second mode but a maximum vibration speed (frequency) at which a laser beam may vibrate may be higher than in the second mode.

The controller 200 may output the vibration signal SV to apply a triangular or square wave to the motor of the vibrator 320 in the second mode, based on the manipulation command. The motor to which an input of the triangular or square wave is applied may accurately determine a vibration amplitude. That is, the vibration speed is lower than in the first mode but a laser beam may vibrate at an amplitude closer to a target vibration amplitude.

The laser beam outputter 300 may include the laser oscillator 310 that oscillates a laser beam and outputs the oscillated laser beam. The laser oscillator 310 may process the object ST by outputting the oscillated laser beam to the optical element 330. The vibrator 320 may vibrate the optical element 330 to vibrate the laser beam incident from the laser oscillator 310 in a direction of vibration. This is to vibrate a laser beam to be input to the condenser lens 400.

For example, the incident laser beam may be a single ray, and as another example, a plurality of laser beams may be output from the laser beam irradiation device 10. When a plurality of laser beams are output, the laser oscillator 310 may include a plurality of oscillation modules for outputting the plurality of laser beams.

Only some components of the laser beam outputter 300 may vibrate during vibration of a laser beam. In other words, the laser oscillator 310 and the condenser lens 400 may be fixed not to vibrate, and the optical element 330 may make a simple harmonic motion according to a driving force of the motor of the vibrator 320. The object ST may be processed accurately and the accumulation of heat may be prevented, compared to when the laser oscillator 310 and the condenser lens 400 vibrate.

A vibration amplitude and a vibration speed of the optical element 330 may be determined by the vibrator 320. For example, the motor of the vibrator 320 may be mechanically connected to the optical element 330 directly or indirectly. Because the optical element 330 outputs a laser beam output from the laser oscillator 310 to the condenser lens 400, the vibrator 320 may control the optical element 330 to determine a vibration amplitude and a vibration speed of a laser beam.

The optical element 330 may include a mirror. That is, the optical element 330 may reflect the laser beam output from the laser oscillator 310 to be output to the condenser lens 400. The vibrator 320 may include at least one of an ultrasound motor and a resonance motor. This is because the technical ideas of the present disclosure to prevent excessive accumulation of heat energy to be applied to the object ST cannot be achieved using a general motor using an electromagnetic force.

The condenser lens 400 may output a laser beam at a certain angle of incidence in a direction perpendicular to a plane of the object ST. The angle of incidence may be greater than or equal to zero degrees and less than or equal to 90 degrees.

The condenser lens 400 may be an objective lens, a short focal-length lens or an F-theta lens. One of the objective lens, the short focal-length lens, and the F-theta lens may be selected as the condenser lens 400 according to a processing method and a user's demand. This will be described below.

The laser beam irradiation device 10 according to the embodiment of the present disclosure may vibrate quickly in a direction of vibration different from a direction of processing, thereby increasing the quality and rate of processing. In contrast, in the related art, the quality and speed of processing are low.

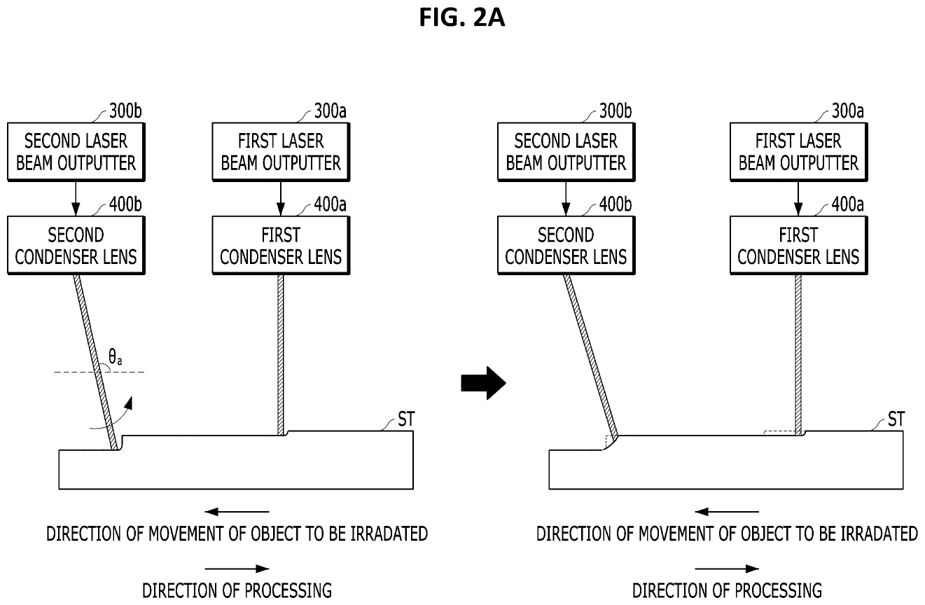

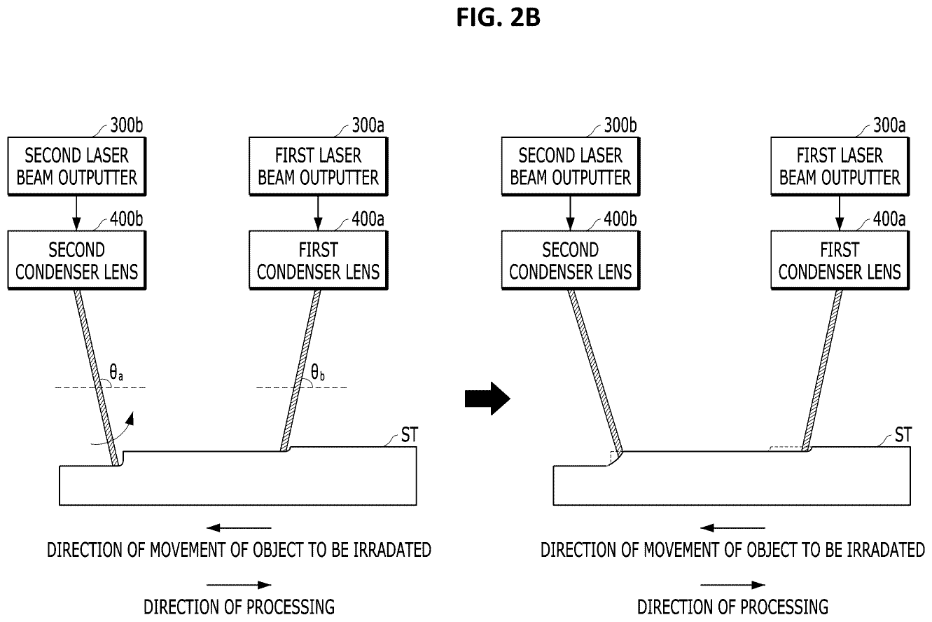

FIGS. 2A and 2B are diagrams for describing a processing method of a laser beam irradiation device according to an embodiment of the present disclosure.

Referring to FIGS. 2A and 2B, the laser beam irradiation device 10 may include a first laser beam outputter 300a and a second laser beam outputter 300b each corresponding to the laser beam outputter 300. The laser beam irradiation device 10 may include a first condenser lens 400a and a second condenser lens 400b each corresponding to the condenser lens 400 described above with reference to FIG. 1.

According to an embodiment of the present disclosure, the laser beam irradiation device 10 may output a first laser to an object ST to be irradiated in a direction of processing for first-time processing, and output a second laser at an angle of incidence, which is different from that of the first laser, in the direction of processing.

According to an embodiment of the present disclosure, the second laser beam outputter 300b may output the second laser to cut the object ST. For example, a cut surface may be formed on the object ST by the second laser. The first laser beam outputter 300a may output the first laser to perform pre-processing for cutting the object ST while securing mass-production quality. Here, the mass-production quality may be referred to as target quality to be achieved by a performer who performs processing, and may include, for example, uniformity of a cross-section, a cutting speed, a cut size, a line width, etc. When the object ST is, for example, a wafer, the first laser beam outputter 300a may output the first laser to remove a compound from a surface of a semiconductor.

According to an embodiment of the present disclosure, the second laser beam outputter 300b may output the second laser on a path on which pre-processing is performed by the first laser beam outputter 300a. That is, an area of the object ST prepared to be processed by the first laser beam outputter 300a may be processed (e.g., cut) by the second laser beam outputter 300b. In this sense, the first laser may be referred to as primary laser, and the second laser may be referred to as secondary laser.

According to an embodiment of the present disclosure, the first laser beam outputter 300a may output a laser of a wavelength smaller than a wavelength of a laser output from the second laser beam outputter 300b. According to an experiment, when a first laser beam of a wavelength of 515 nm to 532 nm or a wavelength of 266 nm to 355 nm is output from the first laser beam outputter 300a, a surface of the object ST may be modified without causing irregularities. This is because the first laser beam of the wavelength described above may be easily absorbed by a material, such as a metal, ceramic or a compound, of the surface of the semiconductor wafer.

According to an embodiment of the present disclosure, an intensity of a laser output from the first laser beam outputter 300a may be substantially the same as or higher than that of a laser output from the second laser beam outputter 300b. According to an experiment, when an average output power of a primary laser output from the first laser beam outputter 300a is high, the object ST may be processed to an excessive depth. This may interfere with securing processing quality when processing (e.g., cutting) is actually performed by the second laser beam outputter 300b. Thus, the intensity of the first laser (i.e., the primary laser) may be higher than the intensity of the second laser (i.e., the secondary laser) but an average output power of the first laser may be lower than that of the second laser.

Referring to FIG. 2A, the first laser beam outputter 300a may output the first laser to the object ST in a direction perpendicular to the object ST, and the second laser beam outputter 300b may output the second laser at a first angle θa in a direction of processing. The first angle θa may be greater than 90 degrees and less than 180 degrees.

In addition, the first laser beam outputter 300a may output the first laser to be perpendicular to the object ST in the direction of processing without making a vibration movement, and the second laser beam outputter 300b may output the second laser vibrating in the direction of processing.

Referring to FIG. 2B, the first laser beam outputter 300a may output the first laser at a second angle θb in the direction of processing. Here, the second angle θb may be greater than zero degrees and less than 90 degrees. When the object ST is sensitive and vulnerable to laser beams, the first laser may be output at an acute incidence angle so that the quality of processing the object ST by the second laser beam outputter 300b may be further increased. An output of the first laser of the acute incidence angle is higher than that of first laser of an incidence angle in a vertical direction and thus target processing quality may be achieved even when the first laser of the acute incidence angle is output to the object ST. Therefore, surface removal and depth processing may be more easily performed at once with higher energy.

Unlike the description above with reference to FIG. 2A, the first laser beam outputter 300a may output a first laser making a vibration motion, i.e., a first laser vibrating in the direction of processing. For example, when vibration is applied to the first laser, the object ST formed of thick materials may be processed (e.g., cut) more effectively and quickly using both the first laser and the second laser. However, embodiments are not limited thereto, and the first laser beam outputter 300a may output a first laser at the second angle θb without vibration.

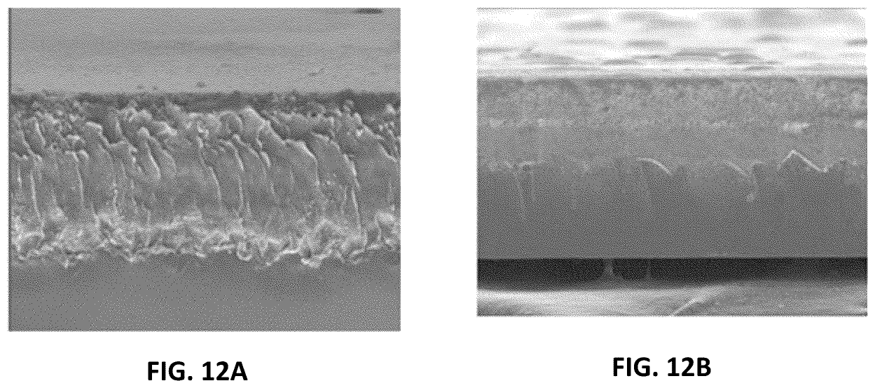

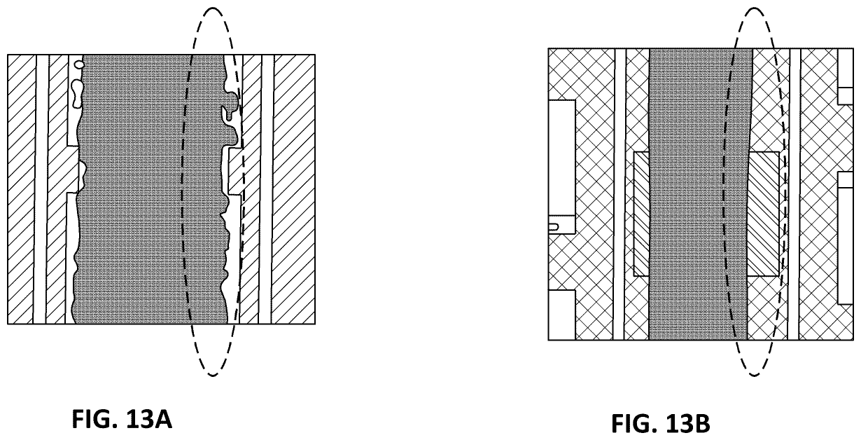

Referring to FIGS. 2A and 2B, the object ST (e.g., a semiconductor wafer) may be fully cut by continuously performing a cutting operation by a primary laser (i.e., the first laser) and a secondary laser (i.e., the second laser). In other words, in the related art, when fully cutting of an object to be irradiated is attempted with a single laser, mass-production quality is not achieved due to an excessive laser beam output (e.g., FIGS. 12A and 13A). However, according to an embodiment of the present disclosure, the qualities of the object ST and a result of mass-production using the object ST may be secured by pre-processing using a primary laser, and mass production quality may be achieved by full-cutting using a secondary laser. In addition, by using the primary laser and the secondary laser, outputs of the primary laser and the secondary laser may be reduced to prevent the accumulation of heat in the object and the deformation of a material of the object ST.

FIGS. 3A and 3B are diagrams for describing blade dicing and stealth dicing of the related art.

Referring to FIG. 3A, a thin cutting blade formed of micro-diamond is rotated at a high speed by a blade dicing device. That is, the blade dicing device cuts an object using saw teeth of the cutting blade.

In this process, a cut portion of a surface or back of a substrate on which the cutting blade is located may be irregularly torn by the cutting blade during the cutting of the object (e.g., the substrate). Chipping of the substrate may occur when the object is torn. This may be a major cause that reduces the performance of chips divided from the object by dicing.

However, in a method of irradiating a laser beam, a strong output of a laser beam is irradiated on a local area, thereby preventing performance degradation.

In contrast, referring to FIG. 3B, a stealth dicing device may concentrate a laser beam on a local area of an object to form internal cracks for cutting the object. The object may split along the cracks in a certain pattern. In the splitting of the object, an irregular cut surface may be formed on an area adjacent to the cracks. In addition, a laser beam used for stealth dicing has excessively high peak power and thus undesired cracks may further occur in a surface of a semiconductor, resulting in degradation of the performance of chips.

However, according to the embodiment of the present disclosure, the object ST is fully cut by a laser beam and thus a removal process need not be additionally performed, thereby preventing a cause that reduces performance. In addition, even when a laser beam having high peak power is used as in stealth dicing, a time during which the laser beam remains on a certain area may be remarkably reduced using vibration, compared to when stealth dicing is used, and thus the deformation of the object ST due to the accumulation of heat energy may be prevented.

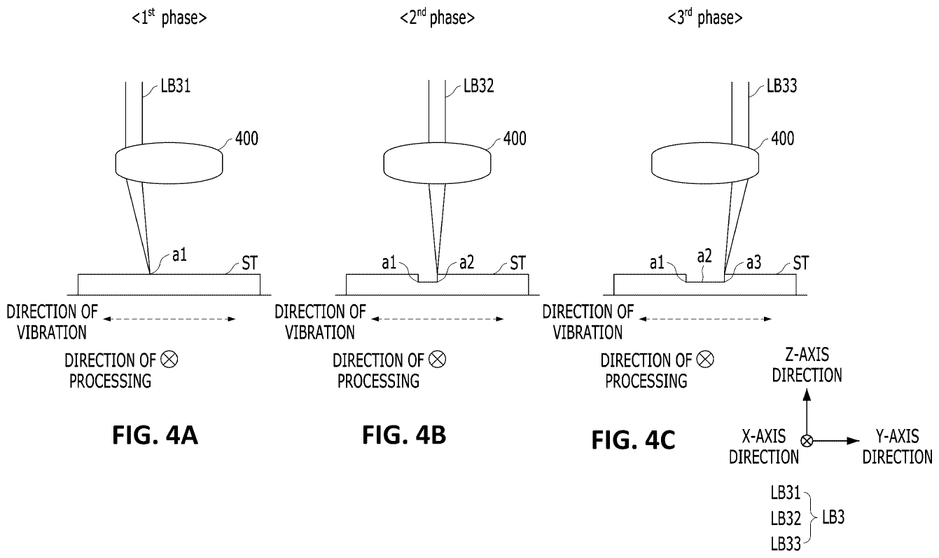

FIGS. 4A to 4C are diagrams for describing a method of vibrating a laser beam according to an embodiment of the present disclosure. The method will be described in a time-series manner in the order of FIGS. 4A to 4C.

Referring to FIGS. 4A to 4C, the laser beam irradiation device 10 may vibrate a laser beam LB3 to output the laser beam LB3 on different positions on a condenser lens 400. For convenience of description, different reference numerals, e.g., LB31 to LB33, are assigned to laser beams at first, second and third stages but the laser beams LB31 to LB33 should be understood to be one laser beam output from the same laser oscillator 310. However, embodiments are not limited thereto, and the laser beams LB31 to LB33 may be laser beams output from different oscillators.

To describe it in a time series manner, first, the laser beam irradiation device outputs the laser beam LB31 onto an edge area of the condenser lens 400. Next, the laser beam irradiation device 10 outputs the laser beam LB32 onto a central area of the condenser lens 400 through vibration. Thereafter, the laser beam irradiation device 10 may output the laser beam LB33 onto an edge region of the condenser lens 400, which is opposite to the edge area at the first stage, through vibration. The laser beam irradiation device 10 may form a laser spot LS on different areas a1 to a3 of an object ST to be irradiated. The laser beam irradiation device 10 may process the areas a1 to a3 that are spaced a small distance from one another in an x-axis direction but are spaced a vibration distance (a processing width or a line width) from one another in a y-axis direction. Here, the vibration distance may correspond to a line width of a conductor. That is, the laser beam irradiation device may vibrate by the line width in the y-axis direction.

According to an embodiment of the present disclosure, the laser beam irradiation device 10 may vibrate the laser beam LB3 to remain on a local area (e.g., the area a1) only for a time during which the deformation of materials does not occur according to a preset quality criterion.

For example, the controller 200 may transmit a vibration signal SV such that vibration speeds of the vibrator 320 may include at least one of vibration speeds greater than 0 and less than or equal to 20 kHz. In this case, when the controller 200 outputs a vibration signal SV of a vibration speed greater than or equal to 1 kHz, the vibrator 320 may be embodied as an ultrasound motor or a resonance motor.

As another example, the controller 200 may transmit the vibration signal SV such that vibration speeds of the vibrator 320 may include at least one of vibration speeds greater than 0 and less than or equal to 10 kHz.

According to an embodiment, when the laser beam irradiation device 10 receives information indicating that the object ST is a wafer formed of a first material from the inputter 100, the controller 200 may transmit the vibration signal SV of a first frequency to control the laser spot LS to remain on a local area (e.g., the area a1) for a time corresponding to the first frequency.

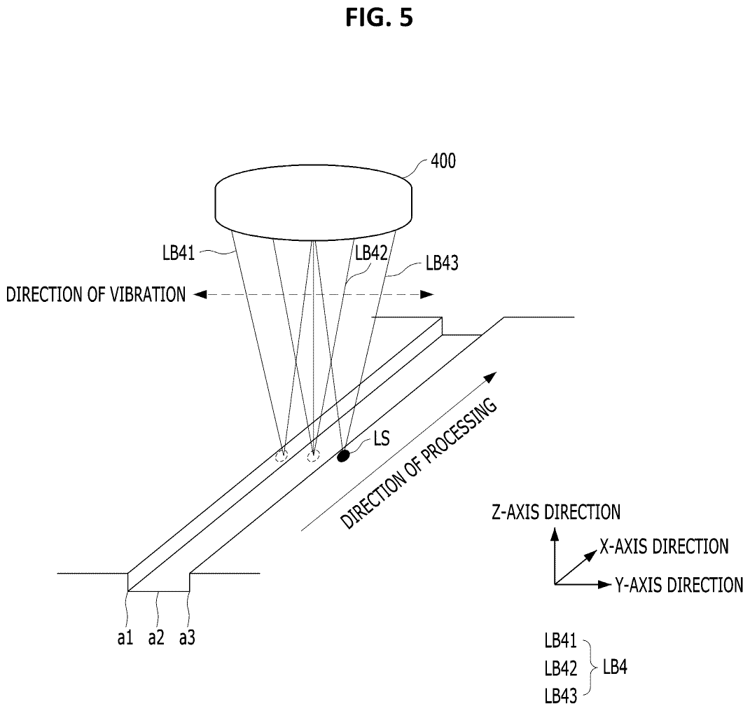

FIG. 5 is a diagram for describing a vibration method, a condenser lens, and a processing method of a laser beam irradiation device according to an embodiment of the present disclosure.

According to an embodiment of the present disclosure, the laser beam irradiation device 10 may form a cut surface having a width corresponding to a vibration distance in the y-axis direction by a laser beam LB4 passing through the condenser lens 400. That is, the laser beam irradiation device 10 may perform a dicing process.

According to another embodiment of the present disclosure, the laser beam irradiation device 10 may form a groove having a width corresponding to the vibration distance in the y-axis direction. That is, the laser beam irradiation device may perform a grooving process.

According to another embodiment of the present disclosure, the laser beam irradiation device 10 may perform a grinding process by vibrating the laser beam LB4 to a large extent in the y-axis direction.

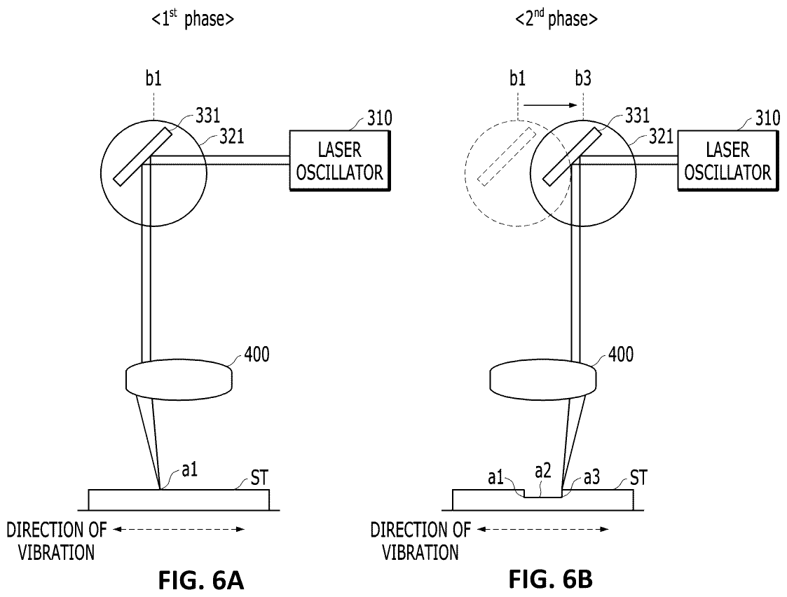

A vibration method of the laser beam irradiation device 10 will be described with reference to FIGS. 6A to 8B below, and mirror vibration, polygon vibration, and light-source vibration will be also described.

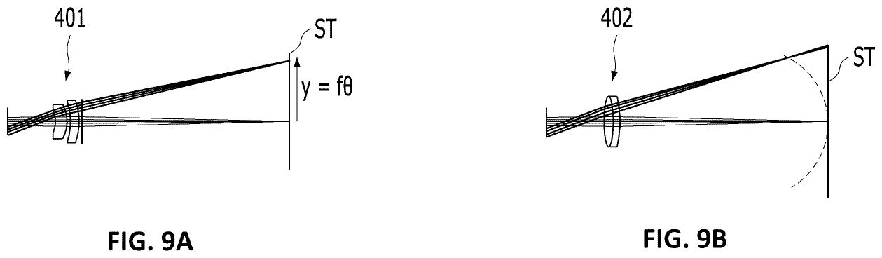

The condenser lens 400 will be described with reference to FIGS. 9A and 9B below, and an objective lens, a short focal-point lens, and an F-theta lens will be also described.

FIGS. 6A and 6B are diagrams for describing mirror vibration among vibration methods according to an embodiment of the present disclosure.

Referring to FIGS. 6A and 6B, a vibrator 320 may include a motor 321, and the motor 321 may include at least one of an ultrasound motor and a resonance motor. An optical element 330 may include a horizontal mirror 331.

According to an embodiment of the present disclosure, the horizontal mirror 331 may be mechanically connected to the motor 321, a driving force of the motor 321 may be transmitted to the horizontal mirror 331, and the horizontal mirror 331 may make a simple harmonic oscillation. In this case, a frequency of the simple harmonic oscillation may be substantially the same as a vibration speed at which the laser beam irradiation device 10 vibrates in a direction of vibration that is different from a direction of processing.

According to an embodiment of the present disclosure, the optical element 330 may vibrate in a direction parallel to the condenser lens 400. Accordingly, a laser beam may vibrate while moving back and forth between two points symmetrical to a central point, or the origin, on the condenser lens 400.

According to an embodiment of the present disclosure, the optical element 330 may vibrate in a direction in which a laser output from the laser oscillator 310 is incident on the optical element 330. In this case, the optical agent 330 may be a plane mirror that reflects the laser output from the laser oscillator 310 to the condenser lens 400.

According to an embodiment of the present disclosure, the motor 321 may be a vibration motor such as an ultrasound motor or a resonance motor. The vibration motor may generate a high frequency inside the motor 321 to produce a driving force. The driving force of high frequency may be transmitted to the horizontal mirror 331, which is structurally coupled to the motor 321 directly or indirectly, through a transmitter of the motor 321.

Preferably, the motor 321 may generate a frequency greater than or equal to 1 kHz and less than or equal to 20 kHz. That is, at least one of the ultrasound motor and the resonance motor may vibrate a laser beam at a frequency greater than or equal to 1 kHz and less than or equal to 20 kHz to discharge emissions (e.g., dust, particles, or debris), which are generated during processing of a semiconductor, by the vibrating laser beam, thereby increasing process yield. Several experiments showed that an effect according to an embodiment of the present disclosure was not achieved with a frequency less than 1 kHz of a linear actuator motor, which is generally used, but at a low frequency greater than or equal to 1 kHz and less than or equal to 20 kHz, a thermal deformation rate of the object ST decreased remarkably while emissions were removed by a laser beam.

Referring to FIG. 6A, at a first stage, the horizontal mirror 331 may be located at a point b1. Next, referring to FIG. 6B, the horizontal mirror 331 may be moved from the point b1 to a point b3 by a driving force (vibration) of the motor 321. Thereafter, the horizontal mirror 331 may be moved back and forth between the point b3 and the point b1 by the driving force (vibration) of the motor 321.

That is, the laser beam irradiation device 10 according to the embodiment of the present disclosure may output a laser beam, which vibrates in a direction of vibration, to the object ST using the driving force of the motor 321 and the vibration of the horizontal mirror 331 based on the driving force.

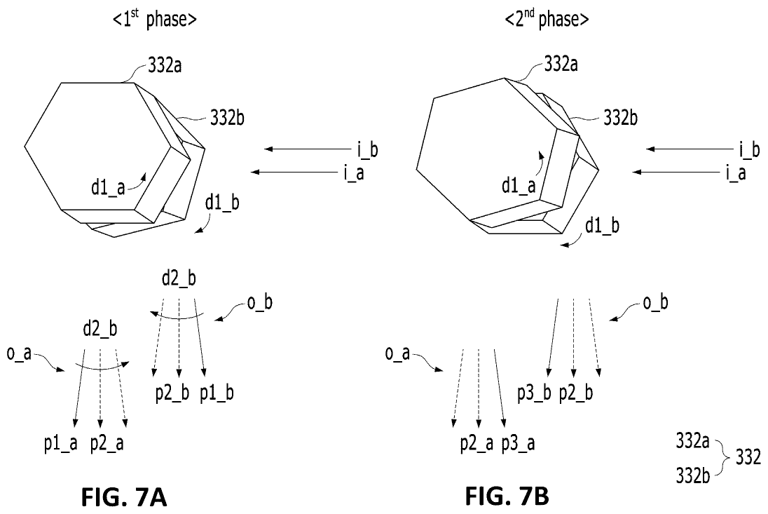

FIGS. 7A and 7B are diagrams for describing polygon vibration among vibration methods according to an embodiment of the present disclosure.

Referring to FIGS. 7A and 7B, the optical element 330 may include a pair of polygonal mirrors 332, and the pair of polygonal mirrors 332 may include a first polygonal mirror 332a and a second polygonal mirror 332b each having a plurality of reflective surfaces.

According to an embodiment of the present disclosure, the laser oscillator 310 may include a plurality of oscillation modules. For example, the laser oscillator 310 may output a plurality of laser beams, including a first laser beam i_a and a second laser beam i_b. The laser oscillator 310 may output the first laser beam i_a to the first polygonal mirror 332a and the second laser beam i_b to the second polygonal mirror 332b.

The first polygonal mirror 332a may rotate in a first direction d1_a, and the second polygonal mirror 332b may rotate in a second direction d1_b opposite to the first direction d1_a. For example, the vibrator 320 may be embodied as a rotary motor and rotate the first polygonal mirror 332a and the second polygonal mirror 332b in different directions. As another example, the vibrator 320 may be embodied as a vibration motor and output a driving force (vibration) to a plurality of polygonal mirrors such that the first polygonal mirror 332a and the second polygonal mirror 332b vibrate with opposite phases.

According to an embodiment of the present disclosure, when the optical element 330 includes the pair of polygonal mirrors 332, reflected output laser beams o_a and o_b may be output to the object ST. In this case, the reflected output laser beams o_a and o_b may vibrate in different directions.

Alternatively, the reflected output laser beams o_a and o_b may vibrate unidirectionally. For example, the first output laser beam o_a may vibrate in an order of a first point p1_a, a second point p2_a, a third point p3_a, the first point p1_a, the second point p2_a, . . . on the object ST. The second output laser beam o_b may vibrate in an order of a fourth point p1_b, a fifth point p2_b, a sixth point p3_b, the fourth point p1_b, the fifth point p2_b, . . . on the object ST. That is, when the output laser beams o_a and o_b respectively reach the third point p3_A and the sixth point p3_b, the output laser beams o_a and o_b respectively return back to the first point p1_a and the fourth point p1_b. This is due to the form of the polygonal mirrors.

That is, according to an embodiment of the present disclosure, when the optical element 330 includes the pair of polygonal mirrors 332, the laser beam irradiation device 10 may process the object ST by outputting to the object ST the output laser beams o_a and o_b making simple harmonic oscillation in different directions. In this case, the directions of the simple harmonic oscillation may be different from a direction of processing the object ST.

Meanwhile, the output laser beams o_a and o_b may be output to the object ST through the condenser lens 400.

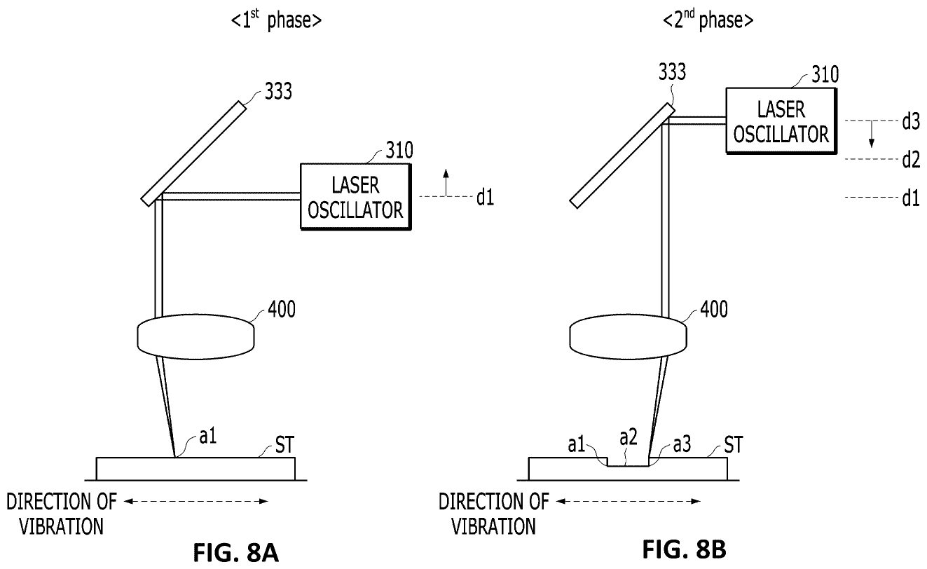

FIGS. 8A and 8B are diagrams for describing light-source vibration among vibration methods according to an embodiment of the present disclosure.

Referring to FIGS. 8A and 8B, the optical element 330 may include a fixed horizontal mirror 333.

According to an embodiment of the present disclosure, the laser oscillator 310 may be mechanically connected to the vibrator 320 directly or indirectly to deliver a driving force (vibration). Unlike in FIG. 5, the fixed horizontal mirror 333 and the condenser lens 400 may be fixed not to vibrate, and the laser oscillator 310 may be vibrated by the vibrator 320. For example, the laser oscillator 310 may be moved to a point d3 starting from a point d1 and thereafter make simple harmonic oscillation while moving back and forth between the point d3 and the point d1.

According to an embodiment of the present disclosure, the object ST may be processed in a direction of vibration from the point a1 to the point a3 due to vibration of the laser oscillator 310.

FIGS. 9A and 9B are diagrams for describing a condenser lens according to an embodiment of the present disclosure.

Referring to FIG. 9A, the condenser lens 400 may be embodied as an F-theta lens 401, and FIG. 9B is a diagram for describing an achromatic lens 402. Curvature of image field may not occur on the f-theta lens 401 unlike the achromatic lens 402.

The laser beam irradiation device 10 according to the embodiment of the present disclosure may be used to process a semiconductor in nano-scale units. When curvature of image field occurs as on the achromatic lens 402, a vibration amplitude cannot be adjusted finely and thus effects according to the technical idea of the present disclosure may be difficult to achieve. Accordingly, the laser beam irradiation device 10 may adjust a vibration amplitude accurately using the f-theta lens 401.

The condenser lens 400 according to the embodiment of the present disclosure may include a short focal length lens, a singlet lens, and a bi-convex lens. The condenser lens 400 according to the embodiment of the present disclosure may include an objective lens. In this case, the objective lens may have a magnification of 5 times or more to 100 times or less. The objective lens is optimized to form a fine laser spot LS, compared to the f-theta lens 401 described above. According to an experiment, when the condenser lens 400 is an objective lens among the lenses described above, the laser spot LS may have a smallest clear diameter. This will be described with reference to FIGS. 9A and 9B below.

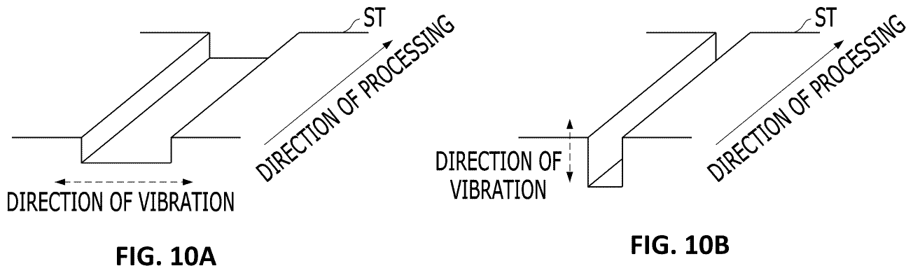

FIGS. 10A and 10B are diagrams for describing a direction of vibration and a direction of processing determined by a processing method according to an embodiment of the present disclosure.

Referring to FIG. 10A, the laser beam irradiation device 10 may output a laser beam in the direction of processing while vibrating narrowly in a horizontal direction.

Accordingly, when the object ST is embodied as a wafer, the laser beam irradiation device 10 may perform at least one of grooving, scribing, removing, and grinding.

Referring to FIG. 10B, the laser beam irradiation device 10 may output a laser beam in the horizontal direction while vibrating narrowly and deeply in a vertical direction (a perpendicular direction).

Accordingly, the laser beam irradiation device 10 may perform dicing when the object ST is embodied as a wafer.

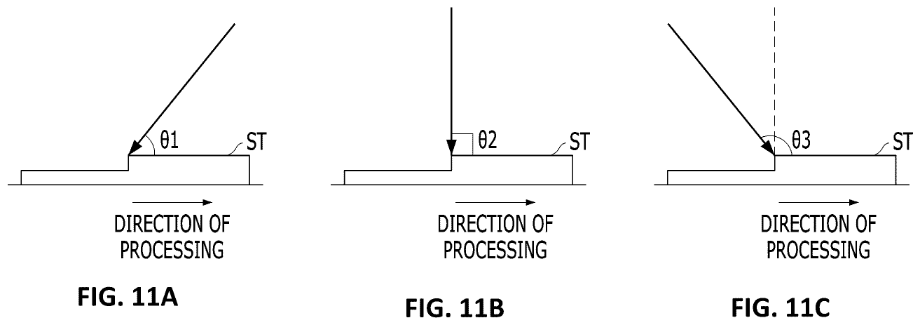

FIGS. 11A to 11C are diagrams for describing a direction of processing and an angle of incidence according to an embodiment of the present disclosure.

Referring to FIGS. 11A, 11B and 11C, the laser beam irradiation device 10 may perform forward processing, vertical (perpendicular) processing or backward processing according to an angle of incidence. In the case of forward processing, the laser beam irradiation device 10 may output a laser beam onto an object ST to be irradiated at an acute angle θ1 in a direction of processing. In the case of vertical (perpendicular) processing, the laser beam irradiation device 10 may output a laser beam onto the object ST at a right angle θ2 in the direction of processing. In the case of backward processing, the laser beam irradiation device 10 may output a laser beam onto the object ST at an obtuse angle θ3 in the direction of processing. The use and usefulness of each of the processings described above are as described above and thus description thereof will be omitted.

According to an embodiment of the present disclosure, a depth to which the laser beam irradiation device 10 penetrates the object ST may vary according to an angle of incidence of a laser beam. For example, the laser beam irradiation device may perform vertical processing when etching is performed to a first depth, and perform forward processing or backward processing when etching is performed to a second depth less than the first depth.

FIGS. 12A to 13B are images taken by an electron microscope for describing the qualities of semiconductor processing results according to an embodiment of the present disclosure and a comparative example.

FIG. 12A is a cross-sectional view of a result of dicing an object ST to be irradiated according to a comparative example, and FIG. 12B is a cross-sectional view of a result of dicing the object ST according to an embodiment of the present disclosure.

According to the comparative example, irregular areas occurred on both a surface and a cross section of the object ST, resulting in degradation of processing quality.

However, according to the embodiment of the present disclosure, it can be seen that a cross section was smooth and surface burst due to the laser did not occur, and thus processing quality was high.

FIGS. 13A and 13B are images captured in a vertical direction of semiconductors processed by a line width according to comparative examples and embodiments of the present disclosure.

According to the comparative examples, it was confirmed that by irradiating a strong laser beam without vibration in a direction of processing, not only a target area of an object to be irradiated but also a non-target area thereof were damaged by strong heat of the laser beam.

However, according to the embodiments of the present disclosure, by irradiating a laser beam with appropriate strength in the direction of processing while vibrating the laser beam in a direction of vibration, areas excluding the target area were not damaged by the laser beam.

According to an embodiment of the present disclosure, heat energy can be dispersed by vibrating a laser beam on a local area to prevent the accumulation of heat energy unlike in stealth dicing, thereby preventing destruction and deformation of a material of a semiconductor.

According to an embodiment of the present disclosure, the qualities of an object to be irradiated and a result of mass-production using the object can be secured by pre-processing using a primary laser, and mass-production quality can be achieved by full-cutting using a secondary laser.

According to an embodiment of the present disclosure, a semiconductor can be accurately processed by easily determining a processing parameter (e.g., a line width) by a diameter of a laser spot to be adjusted according to a lens.

According to an embodiment of the present disclosure, process yield can be increased by removing emissions (e.g., dust, particles, and debris) generated during processing of a semiconductor by a vibrating laser beam.

According to an embodiment of the present disclosure, a result customized for a manufacturer's needs may be obtained by adjusting an angle of incidence of a vibrating laser beam to an acute angle, a right angle or an obtuse angle.

As described above, example embodiments are set forth in the drawings and the present specification. Although the embodiments have been described herein using specific terms, the terms are only used to describe the technical idea of the present disclosure and thus should not be understood as limiting the meaning and the scope of the present disclosure described in the claims. Therefore, it will be understood by those of ordinary skill in the art that various modification may be made and equivalent embodiments may be achieved. Therefore, the technical scope of the present disclosure should be defined by the technical idea of the appended claims.

What is claimed is:

1. A laser beam irradiation device for processing a semiconductor, comprising:
a laser beam outputter configured to cause a laser beam to travel in a direction of processing to process a semiconductor, and to vibrate the laser beam at a constant amplitude in a direction of vibration different from the direction of processing; and
a condenser lens configured to form a laser spot on the semiconductor, the laser spot traveling in the direction of processing and vibrating in the direction of vibration.

2. The laser beam irradiation device of claim 1, wherein the laser beam outputter outputs a first laser to the semiconductor in the direction of processing for first-time processing, and outputs a second laser at an incidence angle, which is different from an incidence angle of the first laser, in the direction of processing.

3. The laser beam irradiation device of claim 2, wherein the laser beam outputter comprises:
a first laser beam outputter configured to output the first laser to perform pre-processing for cutting the semiconductor while securing high processing quality; and
a second laser beam outputter configured to output the second laser for forming a cut surface on the semiconductor.

4. The laser beam irradiation device of claim 3, wherein the laser beam outputter further comprises:
a laser oscillator configured to oscillate and output the laser beam; and
a vibrator configured to physically vibrate an optical element to vibrate the laser beam, which is incident from the laser oscillator, in the direction of vibration.

5. The laser beam irradiation device of claim 4, wherein the laser oscillator and the condenser lens are fixed not to vibrate, and the optical element makes a simple harmonic motion due to a driving force of a motor of the vibrator.

6. The laser beam irradiation device of claim 5, wherein the optical element comprises a horizontal mirror, and
the motor comprises at least one of an ultrasound motor and a resonance motor.

7. The laser beam irradiation device of claim 6, further comprising:
an inputter configured to receive a manipulation command for processing the semiconductor; and
a controller configured to control the vibrator to apply an input of a sine wave to the motor in a first mode, and apply a triangular or square wave to the motor in a second mode, based on the manipulation command.

8. The laser beam irradiation device of claim 7, wherein the first mode is a user mode selected by a user who assigns priority to a vibration speed of the laser beam, and
the second mode is a user mode selected by a user who assigns priority to a vibration amplitude of the laser beam.

9. The laser beam irradiation device of claim 4, wherein the optical element comprises a pair of polygonal mirrors each having a plurality of reflective surfaces, wherein the pair of polygonal mirrors rotate in different directions.

10. The laser beam irradiation device of claim 1, wherein the semiconductor comprises a semiconductor substrate, and
the condenser lens outputs the laser beam at an angle of incidence in a direction perpendicular to a plane of the semiconductor.

11. The laser beam irradiation device of claim 10, wherein the angle of incidence substantially coincides with a right angle, and
the laser beam outputter vibrates the laser beam at a vibration amplitude in the direction of vibration to correspond to a distance determined by a line width of the semiconductor substrate.

12. The laser beam irradiation device of claim 10, wherein the angle of incidence is greater than 0 degrees and less than 90 degrees, and
the laser beam outputter processes the substrate by a depth to which the laser beam tilted by the angle of incidence is incident on the semiconductor substrate.

13. An operation method of a laser beam irradiation device for processing a semiconductor, comprising:
outputting a first laser beam to perform pre-processing for cutting an object to be irradiated while securing mass-production quality;
outputting a second laser beam to cut the object on a path on which pre-processing is performed based on the first laser beam; and
vibrating the second laser beam in a direction of processing, wherein the first laser beam is output at an angle perpendicular to the direction of processing and is not vibrated unlike the second laser beam, and the second laser beam is output at a first angle perpendicular to the direction of processing.

14. The operation method of claim 13, wherein the first laser beam has a wavelength smaller than a wavelength of the second laser beam.
